(19) United States
(12) Patent Application Publication
(10) Pub. No.: US 2007/0201545 A1
(43) Pub. Date: Aug. 30, 2007

(54) Equalizer gain control system and method

(76) Inventors: Eliyahu D. Zamir, Thornhill (CA); Bimal Patel, Mississauga (CA); Mathew Johnson, Waterdown (CA); Mohammad H. Shakiba, Richmond Hill (CA)

Correspondence Address: David B. Cochran, Esq.;Jones Day, North Point, 901 Lakeside Avenue, Cleveland, OH, 44114, US

(21) Appl. No.: 11/649,003

(22) Filed: Jan. 3, 2007

Related U.S. Application Data
(60) Provisional application No. 60/756,239, filed on Jan. 3, 2006.

(51) Int. Cl. H03H 7/30

(52) U.S. Cl. 375/229

(57) ABSTRACT

Systems and method for controlling the gain of an equalizer are provided. In these systems and methods, bit errors in a serial data stream received by an equalizer are detected, and the gain of the equalizer is set in response to the detected bit errors in the serial data stream.

### CROSS REFERENCE TO RELATED APPLICATIONS

This patent application claims priority to U.S. Provisional Application Ser. No. 60/756239 titled “Equalizer Gain Control,” which was filed on January 3, 2006. The entirety of this prior application is hereby incorporated by reference into this patent document.

### BACKGROUND

An equalizer is used to compensate for frequency dependant losses that occur over a transmission medium such as twisted pair, trace, or coax at high data rates. These losses introduce inter-symbol interference (ISI) that can make data recovery at the receiver end of the transmission medium impossible. Typically, an equalizer at the receiver end will compensate for these losses by applying frequency dependant gain so as to negate the transmission medium losses.

As well as being frequency dependant, the loss within a medium is also typically dependant upon the length of the transmission medium. For example, a 30-meter twisted pair cable will have more loss than a 5-meter twisted pair cable. An automatic equalizer typically includes some type of mechanism for determining and applying the correct amount of gain to compensate for these frequency dependant loses. Conventional techniques for carrying out this function include an Automatic Gain Control (AGC) loop for determining the ideal amount of gain to be applied to the signal. Most of these conventional techniques, however, are sensitive to variation in the transmitter-side launch amplitude, or other characteristics of the signal being propagated through the transmission medium. Known techniques for overcoming these types of signal-dependent characteristics, such as launch amplitude, often involve multiple feedback control loops that can cause system instability. Also, these techniques are bulky and can take up a significant amount of silicon area in an integrated circuit embodiment of the equalizer system.

### SUMMARY

Systems and method for controlling the gain of an equalizer are provided. In these systems and methods, bit errors in a serial data stream received by an equalizer are detected, and the gain of the equalizer is set in response to the detected bit errors in the serial data stream.

### BRIEF DESCRIPTION OF THE DRAWINGS

FIG. 1 is a block diagram of an example system for controlling the gain of an equalizer; and

FIG. 2 is a flowchart of an example method for training and then setting the gain of an equalizer.

### DETAILED DESCRIPTION

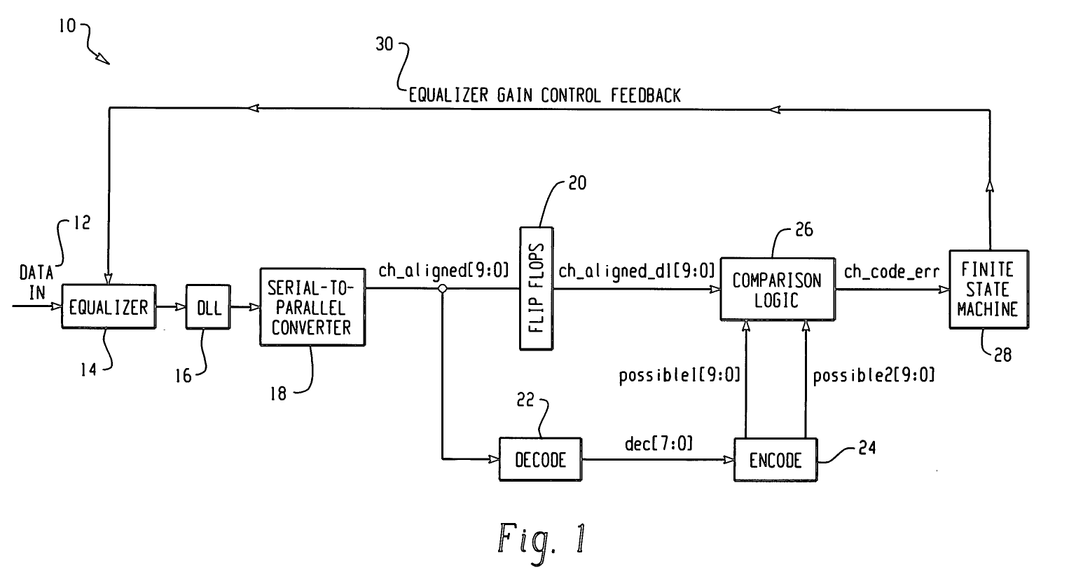

FIG. 1 is a block diagram 10 of an example system for controlling the gain of an equalizer. The system includes an equalizer circuit 14, a delay locked loop (“DLL”) 16, a serial-to-parallel converter 18, an error-detection sub-system including a decode circuit 22, an encode circuit 24, flip flops 20 and comparison logic 26, and finally a finite state machine 28 for processing detected bit errors from the error-detection sub-system and for controlling the gain of the equalizer circuit 14.

Operationally, the system of FIG. 1 receives serial data 12, detects and measures bit errors in the serial data stream 12, and adjusts the gain of the equalizer circuit 14 in order to maximize gain at an acceptable bit error rate. The principal metric for bit error rate (BER) measurements is to look for invalid combinations of detected bits. This is possible, typically, if redundancy exists during signal transmission of the serial data 12. Redundancy in the serial data stream 12 is usually introduced by some sort of coding scheme. For example, in the Digital Visual Interface (DVI) and High Definition Multi-media Interface (HDMI) systems, usage of the Transition Minimized Differential Signaling (TMDS) coding scheme introduces redundant codewords when every 8-bits of original data is mapped to a 10-bit codeword, i.e., an 8b10b system. In these schemes, the 10-bit codewords possess different transition densities depending on whether the content information of the signal is being encoded or is control information. A data enable signal controls the encoder timing by multiplexing between content and control information. Of the 1024 combinations of 10-bit words possible at the receiver, there are 460 valid data codewords and 4 control codewords. There are either only one or two valid 10-bit codewords for each 8-bit data pixel, and either two or three invalid 10-bit codewords that map to the same 8-bit data pixel value. The invalid codewords can be detected, as shown in FIG. 1 and as described in more detail below, by putting TMDS encode logic 24 after the decode block 22, and by checking to see if encoding the 8-bit data results in the received 10-bit codeword.

After passing through the equalization circuit 14, the serial data 12 is then provided to the delay locked loop (“DLL”) 16. The DLL circuit essentially samples the serial data 12, preferably in the center of each received bit. Sampling at the center of each bit, as opposed to close to the rising or falling edge of the signal, is important to avoid phase noise or jitter in the sampled signal. The sampled output of the DLL 16 is then provided to the serial-to-parallel converter 18, which demultiplexes the multi-bit serial data stream into a parallel data bus or data channel. In the example of a 10-bit DVI or HDMI-type signal, the 10-bit serial data stream 12 would be converted into a parallel 10-bit data bus labeled “ch_aligned[9:0],” signifying that the 10-bit channel is aligned along its constitutent bits labeled 0 through 9. The purpose of the converter 18 is also to effectively slow down the data rate by a factor of 10, in this example, so as to ease the subsequent processing steps.

The channel-aligned 10-bit parallel data stream (“ch_aligned[9:0]”) is then processed by the error-detection sub-circuit comprising flip flops 20, decoder 22, encoder 24 and comparison logic 26. In this example system, the 10-bit signal is actually an encoded data signal having 8 bits of data and 2 bits of redundancy. The general purpose of the 2 redundant bits is to provide for a DC-balanced signal. So, if the data part of the signal includes many zeros, then the redundant bits may both be ones in order to DC balance the overall bitstream. Likewise, if the data part of the signal includes many ones, then the redundancy bits will typically be zeros.

Decode circuit 22 receives the 10-bit parallel data stream (“ch_aligned[9:0]”) and converts the signal back into its original 8-bit form that does not include the redundancy bits. This decoded signal (“dec[7:0]”) is then subsequently re-encoded by the encoder circuit 24 into two possible 10-bit signals labeled “possible1[9:0]” and “possible2[9:0].” The two possible encoded data outcomes are dependant upon the previously-processed data bits, and take into account the need to DC balance the signal using the two redundancy bits. So, for example, if the previously processed data bits included a large number of zeros, then one possible outcome may include extra ones as the redundancy bits. But if the previously processed data included a large number of ones, then another possible outcome may include extra zeros as the redundancy bits. In any event, the two posssible outcomes from the encoder circuit 24 are provided as one set of inputs to the comparison logic 26.

The other input to the comparison logic 26 is the ch_aligned[9:0] signal from the serial-to-parallel converter 18. This channel signal is buffered and delayed by the flip flops 20 in order to track the timing delay of the channel signal through the decode 22 and encode 24 circuits. This extra delay is provided (“ch_aligned_dl[9:0]”) so that the comparison logic 26 is comparing the raw and decoded/encoded versions of the received data signal at the same point in time. Comparison logic 26 then compares the ch_aligned_dl[9:0] signal with the encoded possible signals possible1[9:0] and possible2[9:0] to determine if either possible encoded signal matches the delayed raw channel signal ch_aligned_dl[9:0]. If the signals match, then there is no error detected in the signal at the current gain setting of the equalizer 14. If, however, the signals do not match in the comparison logic, then the ch_code_err output signal to the finite state machine 28 indicates that at this gain setting an error has been detected in the data signal 12.

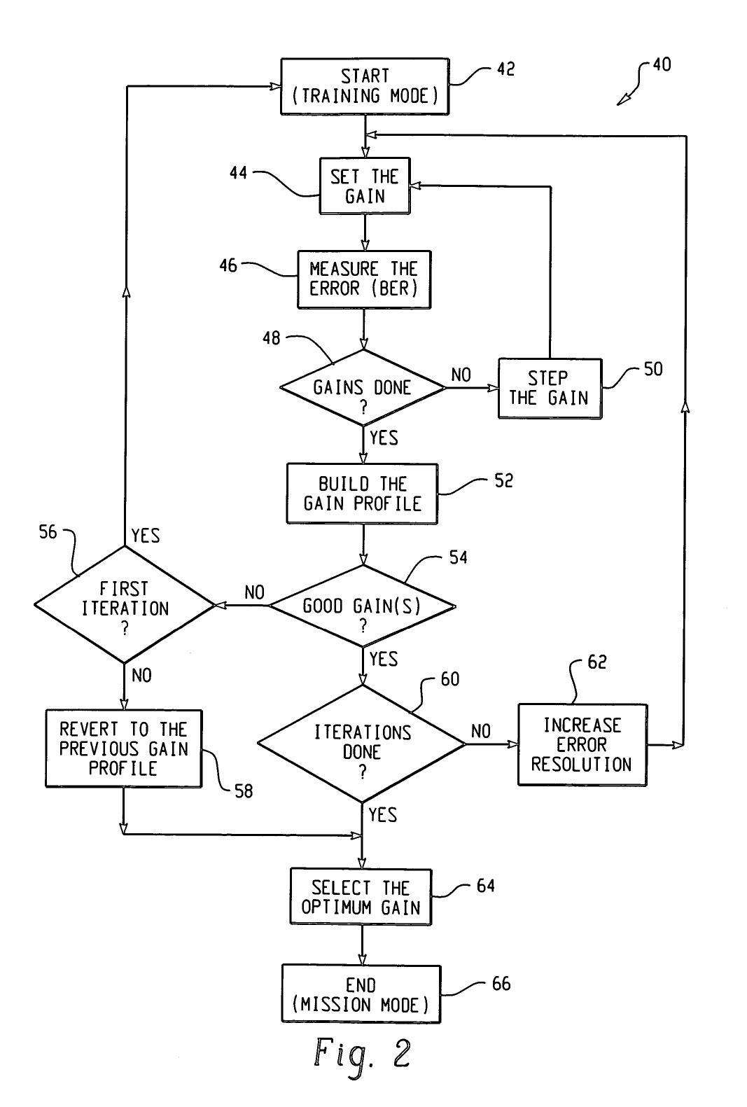

The system 10 is operable in a training mode and a mission mode. During the training mode, the finite state machine 28 steps the equalizer through multiple gain settings and receives measurements of bit error detection (ch_code_err) from the error-detection sub-circuit. These measurements are used by the finite state machine 28 to select the optimal gain for the equalizer 14 which also minimizes detected bit errors. An example algorithm for implementation of this “training” mode by the finite state machine 28 is discussed further in reference to FIG. 2.

FIG. 2 is a flowchart 40 of an example method for training and then setting the gain of an equalizer system 10, preferably via a finite state machine 28. The disclosed methodology allows the system to determine the optimal amount of equalization gain based on maximizing the overall system performance. This approach is different from known commercially-available adaptive equalizers, which adjust the amount of equalization gain by monitoring some aspect or characteristic of the amplified signal and by trying to locally optimize the equalizer performance based on optimizing that particular aspect or characteristic of the signal. In these known approaches, the overall system performance will solely depend upon the degree to which that particular aspect or characteristic of the signal represents and correlates with the overall system performance. By adjusting the gain based upon the information content of the signal, rather than some physical aspect or characteristic, the equalizer gain adjustment algorithm disclosed herein is capable of optimizing system performance even when the transmitter exhibits large variations in its launch swing, for example. The algorithm is also more stable than multiple loop systems and will generally take up less silicon area due to its mostly digital implementation.

Turning then to FIG. 2, the example methodology begins at step 42 when the system 10 is put into the training mode. During this initial training mode, several equalizer gain settings are tested, and the numbers of bit errors in the received signal 12 are detected and counted. After all of the predetermined gain settings are tested, possibly with multiple iterations at different error resolutions, the equalizer control algorithm then selects the best gain setting available for its mission (normal) mode (step 66).

At step 44, an initial gain is selected, typically either at the low or high end of the possible gain settings for the equalizer. Bit errors are then detected and counted at step 46 for a predetermined amount of time. The amount of time during which errors are counted is also refererred to herein as the error resolution, and may be initially set by a user of the system. The longer the amount of time for counting errors, the higher the probability that an error will be detected. Initially, the error resolution is preferably set to a low value, meaning that the amount of time during which errors are detected in step 46 is small. This initial check is relatively fast, however, as compared to later steps employing a higher resolution setting for the error detection, and thus overall minimizes the time spent in the training mode. In step 48, the algorithm checks whether all of the available gain settings for the equalizer have been checked. If all gain settings have been checked, then control passes to step 52. If not, then at step 50 the gain is stepped either up or down to the next available gain setting, the bit errors are measured at step 46, and this process continues until bit error measurements are completed at the initial error resolution of the system. These bit error measurements are then stored as a gain profile in step 52.

After the gain profile is built at step 52, the algorithm then checks the profile at step 54 to determine whether there are any “good” gain settings in the profile, which means that there are gain settings where the bit error measurement was either zero or very low. Preferably, an error threshold can be defined as the maximum number of errors acceptable to the user of the equalizer. This error threshold then dictates the difference between “good” and “bad” gain settings. If there are no “good” gain settings in the profile, then control passes to step 56 where the algorithm determines whether this was the first iteration through the training mode. If this was the first iteration, then the algorithm assumes that the system had not reached steady-state operation and loops back to step 42 to re-start the training mode. If, however, this was not the first iteration of the training mode, then control passes to step 58, in which the algorithm checks a memory for the previously-used gain profile and selects an optimum gain at step 64 from the previoulsy-used gain profile. The system then exits training mode and enters the mission mode 66 in which it normally operates.

Back in step 54, if one or more “good” gain settings were stored in the gain profile 52, then control passes to step 60 in which the algorithm determines whether or not all training iterations are complete. The algorithm may be programmed to iterate over multiple error resolutions in order to iteratively arrive at the optimum gain setting. In doing so, the initial error resolution is set low, meaning that the amount of time spent in the error measurement step 46 is relatively short. In subsequent iterations 60 of the training loop, the error resolution is then stepped up so that the amount of time spent in step 46 is increased. This effectively increases the probability of detecting a bit error and thus decreases the probability of maintaining the “good” gain settings that were previously detected. The system iterates the error resolution at step 62 and returns to step 44 to re-check the “good” gain settings, but now at the higher error resolution to determine if the previously detected “good” settings are still “good.”

After all of the error resolution settings are complete and the gain profile is finalized, the method then proceeds to step 64 in which the optimum gain setting is selected for the equalizer. This selection step 64 typically includes selecting the center of the highest good gain setting island. The “gain setting island” is an area or group of contiguous gain settings that all result in a “good” gain outcome from the training steps. So, for example, if the equalizer included 10 gain settings and gains 4, 5 and 6 were the only “good” settings located after the training iterations, then the optimum gain selection step 64 would select the “center” of the gain island formed by settings 4, 5 and 6, and thus would select gain setting 5 as the optimum setting. The training mode is then complete, and the system enters its mission mode 66 at the optimum gain setting selected at step 64.

The following examples further illustrate what is meant by the “center of the highest good gain setting island” from step 64 of FIG. 2. This gain setting is selected by first identifying the highest continuously-spaced group of gain settings that are below the threshold error rate (i.e., which are identified as “good”), and then selecting the center gain setting from the group.

TABLE 1
Selected gain in BOLD, first example

| | Gain setting | | | | | | | | | |
|---|---|---|---|---|---|---|---|---|---|---|
| | 0 | 1 | 2 | 3 | 4 | 5 | 6 | 7 | 8 | 9 |
| Good/bad | good | good | good | good | bad | good | bad | good | good | good |

TABLE 2
Selected gain in BOLD, second example

| | Gain setting | | | | | | | | | |
|---|---|---|---|---|---|---|---|---|---|---|
| | 0 | 1 | 2 | 3 | 4 | 5 | 6 | 7 | 8 | 9 |
| Good/bad | good | good | good | good | good | good | good | good | good | good |

TABLE 3
Selected gain in BOLD, third example

| | Gain setting | | | | | | | | | |
|---|---|---|---|---|---|---|---|---|---|---|
| | 0 | 1 | 2 | 3 | 4 | 5 | 6 | 7 | 8 | 9 |
| Good/bad | good | good | good | good | good | good | good | good | bad | good |

In the first example shown in Table 1, the highest “good” gain setting island is made up of settings 7, 8, and 9, and the center of this island is gain setting 8. Therefore, gain setting 8 is selected as the optimum gain setting. In the second example shown in Table 2, the highest good gain setting island is made up of settings 0, 1, 2, 3, 4, 5, 6, 7, 8, 9, and the true center of this island is actually between gain settings 4 and 5. In this circumstance, however, the higher of the two middle gain settings is selected, which is gain setting 5. In the third example shown in Table 3, the highest good gain setting island is made up of setting 9, therefore gain 9 is selected.

The equalizer algorithm may also be optimized for even faster performance if a mechanism is provided that can determine the data rate of the signal applied to the equalizer. Due to lower clock rates, very low data rates take the longest for error measurement, and they also require the least amount of equalization. Therefore, when the equalizer control algorithm is aware of the input data rate, the algorithm described previously may be operated with the following differences between low data rates, medium data rates, and high data rates.

At low data rates the frequency-dependent cable attenuation is insignificant and the algorithm is bypassed and gain setting is set to minimum equalization. This will speed up system settling time significantly because the time it takes to measure errors is inversely proportional to the input data rate. At medium data rates, the equalizer performance is not noticeably dependent on the gain setting resolution. Therefore, coarser gain steps are taken. For example, all even gain settings are skipped during iterations of error measurement. This will speed up system settling time significantly because only half the gain settings are now being considered. Finally, at high data rates, the equalizer control algorithm proceeds as explained in connection with FIG. 2, except that the starting error measurement resolution is increased. This is possible because a high input data rate will mean that the error measurement procedure will run faster.

The steps and the order of the steps in the methods and flowcharts described herein may be altered, modified and/or augmented and still achieve the desired outcome. Additionally, the methods, flow diagrams and structure block diagrams described herein may be implemented in the example processing devices described herein by program code comprising program instructions that are executable by the device processing system and/or subsystems. Other implementations may also be used, however, such as firmware or even appropriately designed hardware configured to carry out the methods and flow diagrams or implement the structure block diagrams described herein. Additionally, the methods, flow diagrams and structure block diagrams that describe particular methods and/or corresponding acts in support of steps and corresponding functions in support of disclosed software structures may also be implemented in software stored in a computer readable medium and equivalents thereof. The software structures may comprise source code, object code, machine code, or any other persistently or temporarily stored code that is operable to cause one or more processing systems to perform the methods described herein or realize the structures described herein.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

What is claimed is:

1. A method of controlling the gain of an equalizer, comprising:
detecting bit errors in a serial data stream received by the equalizer; and
setting the gain of the equalizer in response to the detected bit errors in the serial data stream.

2. The method of claim 1, further comprising:
setting the gain of the equalizer at a plurality of gain settings; and
for each of the plurality of gain settings, detecting the bit errors in the serial data stream received by the equalizer at that gain setting.

3. The method of claim 2, further comprising:
comparing the detected bit errors in the serial data stream to a threshold error rate for each gain setting and storing an indication of which gain settings are below the threshold error rate in a gain profile.

4. The method of claim 3, further comprising:
determining whether there are any gain settings in the gain profile that are below the threshold error rate, and if so then identifying the highest continuously-spaced group of gain settings that are below the threshold error rate and selecting the center gain setting from the group.

5. The method of claim 4, wherein if no gain settings are below the threshold error rate, then repeating the setting, detecting and comparing steps until at least one gain setting is below the threshold error rate.

6. The method of claim 5, wherein if no gain settings are below the threshold error rate after repeating the setting detecting and comparing steps, then accessing a previously-stored gain profile and selecting the highest gain setting that is below the threshold error rate.

7. The method of claim 3, further comprising:
setting an initial error resolution for the detecting step;
iterating the setting, detecting and comparing steps at the initial error resolution and at one or more increased error resolutions and storing the indication of which gain settings are below the threshold error rate in the gain profile.

8. The method of claim 1, further comprising:
converting the serial data stream into a parallel data channel comprising N encoded bits, wherein the N encoded bits include one or more redundant bits and a plurality of data bits;
decoding the N encoded bits into a decoded data channel that does not include the redundant bits;
re-encoding the decoded data channel into an encoded data channel comprising N encoded bits; and
detecting bit errors in the serial data stream by comparing the encoded data channel to the parallel data channel.

9. The method of claim 8, wherein the re-encoding step generates a plurality of encoded data channels and wherein the comparing step compares the plurality of encoded data channels to the parallel data channel in order to detect bit errors in the serial data stream.

10. The method of claim 8, wherein the serial data stream comprises DVI or HDMI encoded video data.

11. The method of claim 10, wherein N equals 10 and there are two redundant bits and eight data bits.

12. An equalization system, comprising:
an equalizer for receiving and applying a gain to a serial data stream; and
an error detection and control circuit for detecting bit errors in the serial data stream and for setting the gain of the equalizer.

13. The equalization system of claim 12, wherein the error detection and control circuit sets the gain of the equalizer at a plurality of gain settings and for each setting, detects the bits errors in the serial data stream received by the equalizer.

14. The equalization system of claim 13, wherein the error detection and control circuit further compares the detected bit errors in the serial data stream to a threshold error rate for each gain setting and stores an indication of which gain settings are below the threshold error rate in a gain profile.

15. The equalization system of claim 14, wherein the error detection and control circuit further determines whether there are any gain settings in the gain profile that are below the threshold error rate, and if so it selects the highest gain setting that is below the threshold error rate.

16. The equalization system of claim 12, further comprising:
a delay locked loop coupled to an output of the equalizer for sampling the serial data stream and for providing a sampled serial data stream to the error detection and control circuit.

17. The equalization system of claim 16, further comprising:
a serial to parallel converter coupled to the sampled serial data stream for generating a parallel data channel.

18. The equalization system of claim 17, wherein the parallel data channel comprises N encoded bits, wherein the N encoded bits include one or more redundant bits and a plurality of data bits.

19. The equalization system of claim 18, wherein the error detection and control circuit comprises:
a decoder for decoding the N encoded data bits into N-M decoded data bits, wherein M is the number of redundant bits in the serial data stream;
an encoder coupled to the N-M decoded data bits for generating a re-encoded data channel comprising N bits; and
a comparison device for comparing the re-encoded data channel to the parallel data channel.

20. The equalization system of claim 19, wherein the error detection and control circuit further comprises a finite state machine programmed to operate in a training mode and a mission mode, wherein in the training mode the finite state machine cycles the equalizer through multiple gain settings and measures and records bit error rates at each of the multiple gain settings.

21. The equalization system of claim 12, wherein the serial data stream comprises TMDS encoded video data.
